(19) United States
(12) Patent Application Publication
(10) Pub. No.: US 2010/0129978 A1
(43) Pub. Date: May 27, 2010

(54) Method of fabricating semiconductor device having MIM capacitor

(75) Inventor: Yoon-hae Kim, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/585,066

(22) Filed: Sep. 2, 2009

(30) Foreign Application Priority Data
Nov. 21, 2008 (KR) 10-2008-0116413

(51) Int. Cl. H01L 21/02

(52) U.S. Cl. 438/393; 257/E21.008

(57) ABSTRACT

A method of fabricating a semiconductor device includes forming a first insulating layer on a semiconductor substrate including a first region, forming an electrode pattern embedded in the first insulating layer on the first region, forming a second insulating layer on the first insulating layer and the electrode pattern; forming a recess portion that defines a capacitor region on the first region by etching the first and second insulating layers, wherein the electrode pattern is arranged in the recess portion and a portion of the electrode pattern protrudes from a bottom surface of the recess portion, and forming a dielectric layer and an upper electrode layer on the bottom surface of the recess portion and the protruded portion of the electrode pattern.

### PRIORITY STATEMENT

This application claims priority under 35 USC § 119 to Korean Patent Application No. 10-2008-0116413, filed on Nov. 21, 2008, in the Korean Intellectual Property Office, the entire contents of which are incorporated herein by reference.

### BACKGROUND

1. Field

Example embodiments relate to a method of fabricating a semiconductor device, and more particularly, to a method of fabricating a semiconductor device having a metal-insulator-metal (MIM) capacitor of large capacity without an additional mask process.

2. Description of the Related Art

A polysilicon-insulator-polysilicon (PIP) capacitor includes a polysilicon layer as a capacitor electrode. The PIP capacitor has a limitation in reducing a resistance of the capacitor electrode. In addition, when a bias voltage is applied to the capacitor electrode formed of polysilicon, a depletion region may be formed and the voltage becomes unstable. Accordingly, a capacitance of the capacitor may not be maintained constantly.

Accordingly, research on MIM (metal-insulator-metal) capacitors is being conducted. An MIM capacitor has a structure in which a dielectric layer may be disposed between an upper metal electrode and a lower metal electrode. Because an MIM capacitor is disposed on a semiconductor substrate, a via for wiring and a via for an upper electrode of the MIM capacitor may be formed at different heights from each other, and accordingly, etching an insulating layer for forming the vias may be difficult. The MIM capacitor has a limitation in improving a capacitance due to the limitation in reducing a thickness of a dielectric layer in the MIM capacitor.

### SUMMARY

The present invention provides a method of fabricating a semiconductor device having an MIM capacitor with a relatively large capacitance without an additional mask process.

According to example embodiments, a method of fabricating a semiconductor device including a metal-insulator-metal (MIM) capacitor includes forming a first insulating layer on a semiconductor substrate including a first region, forming an electrode pattern embedded in the first insulating layer on the first region, forming a second insulating layer on the first insulating layer and the electrode pattern, forming a recess portion that defines a capacitor region on the first region by etching the first and second insulating layers, wherein the electrode pattern is arranged in the recess portion and a portion of the electrode pattern protrudes from a bottom surface of the recess portion, and forming a dielectric layer and an upper electrode layer on the bottom surface of the recess portion and the protruded portion of the electrode pattern.

In an example embodiment, the electrode pattern includes a copper (Cu) pattern. Forming the recess portion further includes forming an alignment key to be used in forming the dielectric layer and the upper electrode layer on a remaining portion of the first region except for the recess portion, wherein the alignment key has an etching depth that is equal to a depth of the recess portion. The recess portion and the alignment key are formed simultaneously.

The method may further include forming a third insulating layer on the second insulating layer including the recess portion, wherein the third insulating layer includes a first dual damascene pattern and a second dual damascene pattern that exposes a portion of the upper electrode layer, and forming a first wire in the first dual damascene pattern and a second wire in the second dual damascene pattern, wherein the second wire is electrically connected to the exposed portion of the upper electrode layer.

The first and second wires include copper (Cu) wires. The semiconductor substrate further includes a second region, and forming the electrode pattern may further include forming a conductive pattern on the second region. The second dual damascene pattern exposes a portion of the conductive pattern.

The third insulating layer may further include a third dual damascene pattern that exposes a portion of the conductive pattern, and the exposed portion of the conductive pattern is electrically connected to a third wire arranged in the third dual damascene pattern. The second region includes a memory region and the first region includes a circuit region.

Prior to forming the recess portion and forming the dielectric layer, the method may further include forming a lower electrode layer directly contacting the electrode pattern under the dielectric layer. A portion of the lower electrode layer corresponding to the electrode pattern is exposed by the first dual damascene pattern and directly contacts the first wire. The first dual damascene pattern exposes portions of the lower and upper electrode layers.

In an example embodiment, the electrode pattern may include a plurality of conductive patterns arranged in the recess portion and electrically connected to each other, wherein a portion of the plurality of conductive patterns are exposed by the first dual damascene pattern so as to directly contact the first wire.

In an example embodiment, the electrode pattern may include a plurality of conductive patterns arranged in the recess portion, and a contact pattern arranged on a remaining portion of the first region except for the recess portion and electrically connected to the plurality of conductive patterns, wherein a portion of the contact pattern is exposed by the first dual damascene pattern to directly contact the first wire.

### BRIEF DESCRIPTION OF THE DRAWINGS

Example embodiments will be more clearly understood from the following detailed description taken in conjunction with the accompanying drawings. FIGS. 1-4B represent non-limiting, example embodiments as described herein.

FIG. 1 is a cross-sectional view of a semiconductor device including an MIM capacitor according to an example embodiment;

FIGS. 2A through 2G are cross-sectional views illustrating processes of fabricating the semiconductor device including the MIM capacitor shown in FIG. 1;

FIG. 3A is a cross-sectional view of a semiconductor device including an MIM capacitor according to another example embodiment;

FIGS. 3B and 3C are plan views showing conductive patterns in the semiconductor device shown in FIG. 3A;

FIG. 4A is a cross-sectional view of a semiconductor device including an MIM capacitor according to another example embodiment; and

FIG. 4B is a plan view showing conductive patterns in the semiconductor device shown in FIG. 4A.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will now be described more fully with reference to the accompanying drawings, in which example embodiments are shown. Example embodiments may, however, be embodied in many different forms and should not be construed as being limited to the embodiments set forth herein; rather, these embodiments may be provided so that this disclosure will be thorough and complete, and will fully convey the concept of example embodiments to those skilled in the art. In the drawings, the thicknesses of layers and regions may be exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

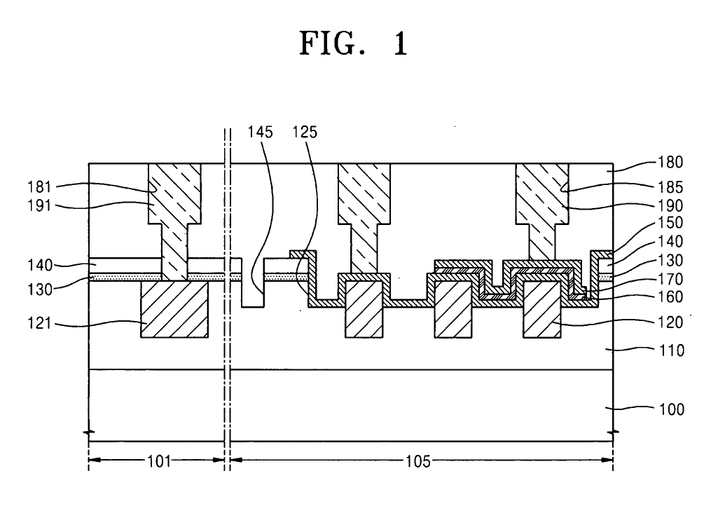

FIG. 1 is a cross-sectional view of a semiconductor device according to an example embodiment. Referring to FIG. 1, a semiconductor substrate 100 may include a memory region 101 on which memory cells may be arranged, and a circuit region 105 on which peripheral circuits may be arranged. A first insulating layer 110 may be disposed on the semiconductor substrate 100. The first insulating layer 110 may include an oxide layer having a low dielectric constant. The first insulating layer 110 may be formed of a fluorine-doped silicate glass layer (FSG layer), hydrogen silsesquioxane layer (HSQ layer), or methyl silsesquioxane layer (MSQ layer or SiOC layer).

First and second conductive patterns 120 and 121 may be disposed in the first insulating layer 110. The first and second conductive patterns 120 and 121 may include copper (Cu) patterns. The second conductive pattern 121 disposed on the memory region 101 may include wire patterns (not shown) connected to a semiconductor device on the substrate 100, for example, a transistor (not shown) disposed under the first insulating layer 110. The first conductive patterns 120 arranged on the circuit region 105 may be electrically connected to a lower electrode layer 150 and perform as lower electrodes of the capacitor. The first conductive patterns 120 may be electrically separated from each other.

An etch stop layer 130 may be disposed on the first insulating layer 110, and a second insulating layer 140 may be disposed on the etch stop layer 130. The etch stop layer 130 may include a nitride layer. The second insulating layer 140 may include a TEOS layer. A recess portion 125 that defines a capacitor region, on which an MIM capacitor will be formed, may be formed throughout the first and second insulating layers 110 and 140 and the etch stop layer 130 on the circuit region 105.

The first conductive patterns 120 may be arranged on the recess portion 125 to perform as lower electrodes of a capacitor. The first conductive patterns 120 may be arranged so that portions of the first conductive patterns 120 protrude from a bottom surface of the recess portion 125, and thus, upper surfaces of the first conductive patterns 120 may be stepped from the bottom surface of the recess portion 125.

The MIM capacitor may be arranged on the recess portion 125. The MIM capacitor may include a lower electrode layer 150 arranged on the recess portion 125, a dielectric layer 160 disposed on the lower electrode layer 150, and an upper electrode layer 170 disposed on the dielectric layer 160. The lower electrode layer 150 may directly contact protruded portions of the first conductive patterns 120, and thus may be formed in a stepped structure. The lower and upper electrode layers 150 and 170 may include one material selected from the group consisting of ruthenium (Ru), ruthenium (IV) oxide (RuO₂), platinum (Pt), iridium (Ir), iridium (III) oxide (Ir₂O₃), strontium ruthenium oxide (SrRuO₃), tantalum nitride (TaN), tungsten nitride (WN), titanium nitride (TiN), titanium aluminum nitride (TiAlN), cobalt (Co), copper (Cu), hafnium (Hf), and alloy thereof. The dielectric layer 160 may include one material selected from the group consisting of silicon nitride (SiN), zirconium oxide (ZrO₂), hafnium (IV) oxide (HfO₂), titanium dioxide (TiO₂), tantalum pentoxide (Ta₂O₅), strontium titanate (SrTiO₃), calcium titanate (CaTiO₃), lanthanum aluminate (LaAIO₃), barium zirconate (BaZrO₃), barium strontium titanate (BaSrTiO₃), barium zirconium titanate (BaZrTiO₃), and strontium zirconium titanate (SrZrTiO₃).

Engraved alignment keys 145 for aligning the MIM capacitor may be formed throughout the first and second insulating layers 110 and 140 and the etch stop layer 130 in the circuit region 105. A third insulating layer 180 may be disposed on the MIM capacitor and the second insulating layer 140. An etch stop layer (not shown) may be further disposed between the second and third insulating layers 140 and 180.

The third insulating layer 180 may include first and second dual damascene patterns 185 and 181. The first dual damascene patterns 185 may expose portions of the lower and upper electrode layers 150 and 170. The second dual damascene patterns 181 may expose a portion of the second conductive pattern 121. A second wire 191 may be arranged in the second dual damascene patterns 181 arranged on the memory region 101 to be electrically connected to the expose portion of the second conductive pattern 121.

First wires 190, which are electrically connected to the lower and upper electrode layers 150 and 170, may be arranged on the first dual damascene patterns 185 that are arranged on the circuit region 105. The first and second wires 190 and 191 may include copper (Cu) wires. The second wire 191 arranged on the memory region 101 may be electrically connected to the second wires 190 arranged on the circuit region 105 for the lower electrode of the capacitor.

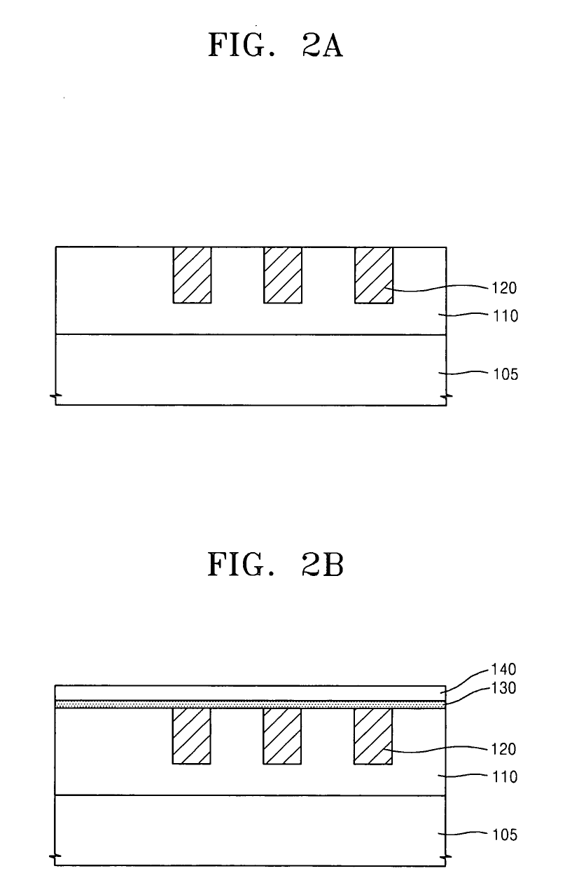

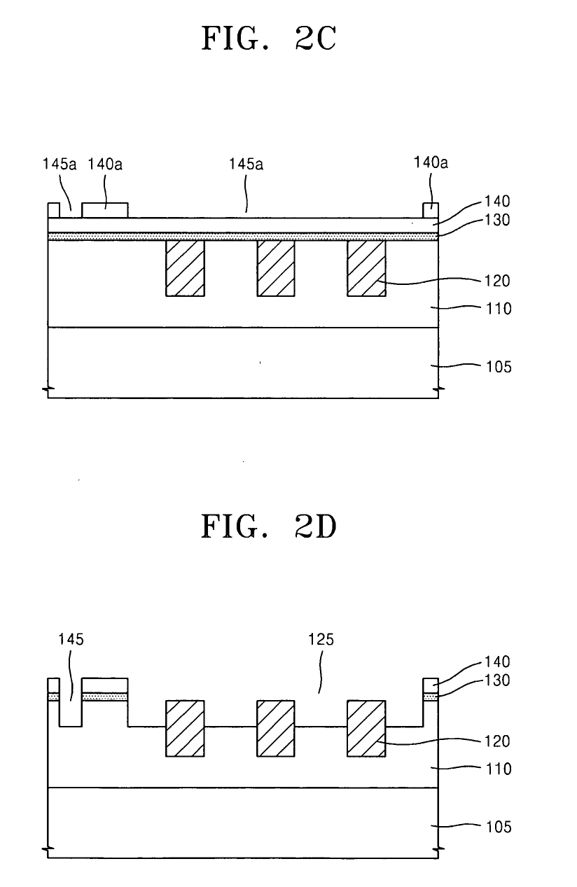

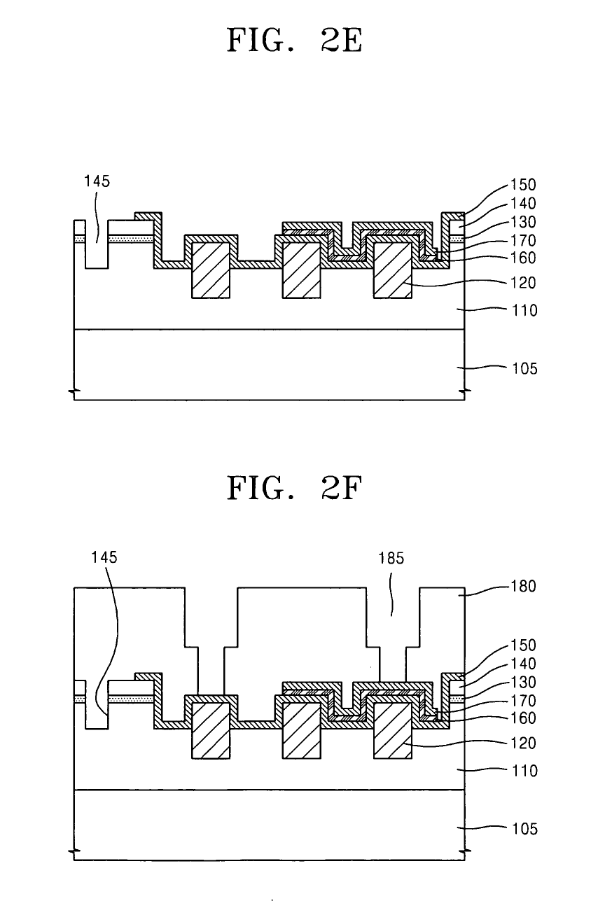

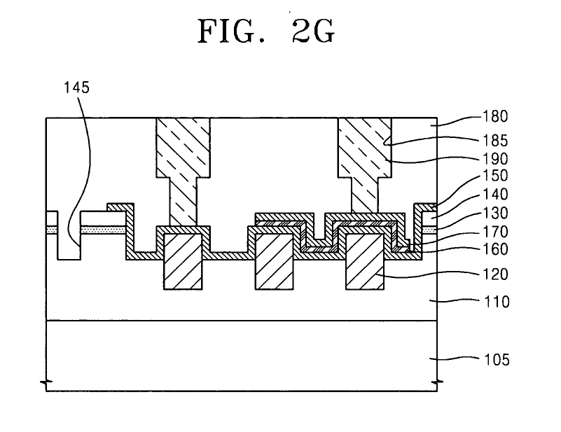

FIGS. 2A through 2G are cross-sectional views illustrating processes of fabricating the semiconductor device including the MIM capacitor shown in FIG. 1; the circuit region 105 in the semiconductor substrate 100 of FIG. 1 is also shown in FIGS. 2A through 2G.

Referring to FIGS. 1 and 2A, the first insulating layer 110 may be formed on the semiconductor substrate 100. The first and second conductive patterns 120 and 121 may be formed on the first insulating layer 110 by performing a single damascene process. The first conductive patterns 120 may be Cu patterns for improving the capacitance of a capacitor, and may be formed when the second conductive pattern 121 is formed on the memory region 101. The first insulating layer 110 may include an oxide layer of a low dielectric constant.

Referring to FIGS. 1 and 2B, the etch stop layer 130 and the second insulating layer 140 may be sequentially formed on the first insulating layer 110 and the first and second conductive patterns 120 and 121. The second insulating layer 140 may include an oxide layer. The etch stop layer 140 may include a nitride layer having an etch selectivity with respect to the oxide layer.

Referring to FIGS. 1 and 2C, a photosensitive layer 140a may be formed on the second insulating layer 140. The photosensitive layer 140a may include openings 145a which expose portions of the second insulating layer 140, in which the alignment key and the recess portion that defines the capacitor region will be formed on the circuit region 105.

Referring to FIGS. 1 and 2D, the first and second insulating layers 110 and 140 and the etch stop layer 130 may be etched using the photosensitive layer 140a as an etching mask to form the alignment key 145 and the recess portion 125. The recess portion 125 may be simultaneously formed when the alignment key 145 is formed without performing an additional mask process. The recess portion 125 may be formed to have the same etching depth as that of the alignment key 145.

Referring to FIGS. 1 and 2E, the lower electrode layer 150, the dielectric layer 160, and the upper electrode layer 170 may be sequentially formed on the second insulating layer 140 including the recess portion 125 and the alignment key 145. A first photolithography process may be performed using the alignment key 145 to pattern the lower electrode layer 150, the dielectric layer 160, and the upper electrode layer 170. In addition, a second photolithography process may be performed using the alignment key 145 to further pattern the dielectric layer 160 and the upper electrode layer 170 so that the dielectric layer 160 and the upper electrode layer 170 are arranged on the lower electrode layer 150. Therefore, the MIM capacitor is formed in the recess portion 125.

Referring to FIGS. 1 and 2F, the third insulating layer 180 may be formed on the second insulating layer 140 including the MIM capacitor and the alignment key 145. The third insulating layer 180 may include an oxide layer. A dual damascene process may be performed to form the second dual damascene pattern 181 that is disposed throughout the second and third insulating layers 140 and 180 and the etch stop layer 130, and to form the first dual damascene patterns 185 that are disposed in the third insulating layer 180. The second dual damascene pattern 181 disposed on the memory region 101 exposes a portion of the second conductive pattern 121. The first dual damascene patterns 185 arranged on the circuit region 105 expose portions of the upper electrode layer 170 and the lower electrode layer 150 of the MIM capacitor.

Referring to FIGS. 1 and 2G, the first and second wires 190 and 191 may be formed in the first and second dual damascene patterns 185 and 181. The first and second wires 190 and 191 may include Cu patterns. The first wires 190 may be electrically connected to the exposed portions of the lower and upper electrode layers 150 and 170, and the second wire 191 may be electrically connected to the exposed portion of the second conductive pattern 121.

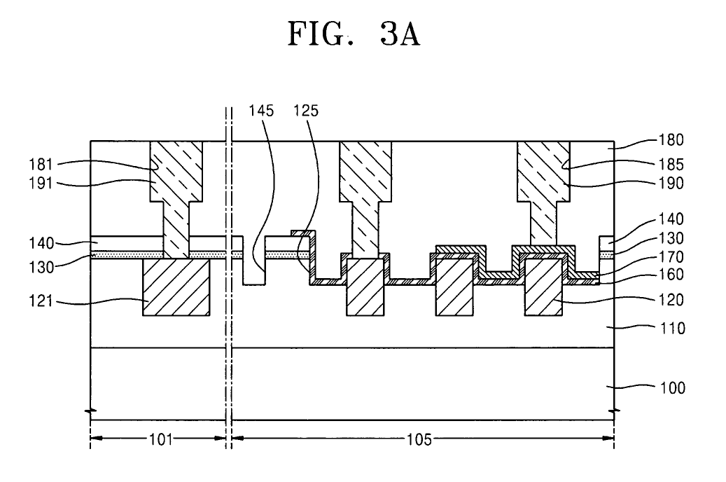

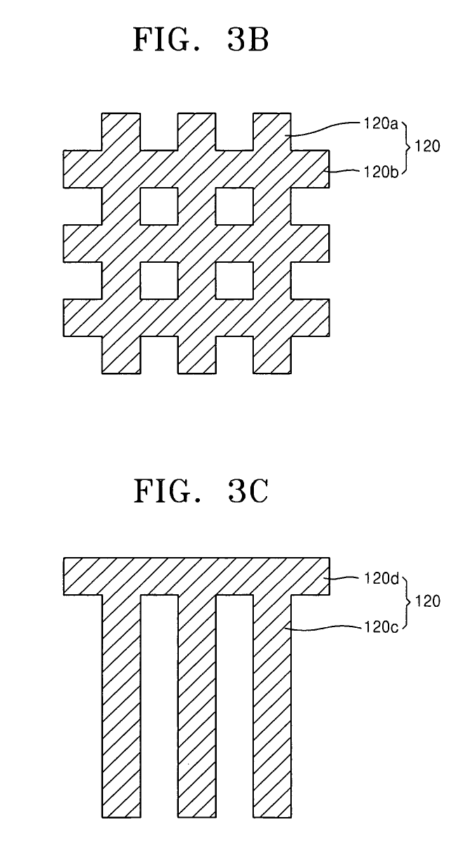

FIG. 3A is a cross-sectional view of a semiconductor device including an MIM capacitor according to another example embodiment, and FIGS. 3B and 3C are plan views of a first conductive pattern 120 shown in FIG. 3A.

Referring to FIGS. 3A through 3C, the semiconductor device of the present example embodiment is different from the semiconductor device shown in FIG. 1 in that the lower electrode of the MIM capacitor only includes a first conductive pattern 120. That is, the single damascene process may be performed to form a second conductive pattern 121 on a memory region 101 of a first insulating layer 130. At the same time, the first conductive pattern 120 that protrudes from the bottom surface of a recess portion 125 may be formed in the recess portion 125 of a circuit region 105. The first conductive pattern 120 performs as a lower electrode of the capacitor.

The first conductive pattern 120 may have a structure in which first conductive lines 120a extending in a first direction and second conductive lines 120b extending in a second direction cross each other and are electrically connected to each other as shown in FIG. 3B, or may have a structure in which conductive lines 120c extending in a first direction are electrically connected to each other by a common conductive line 120d extending in a second direction, as shown in FIG. 3C. The first conductive pattern 120 may have any structure including electrically connected steps so as to perform as the lower electrode of the capacitor.

A dielectric layer 160 and an upper electrode 170 may be sequentially stacked on the second insulating layer 140 which includes the first conductive pattern 120 disposed in the recess portion 125 and the alignment key 145. The first photolithography process may be performed using the alignment key 145 in order to pattern the dielectric layer 160 and the upper electrode layer 170. The dielectric layer 160 is formed so as to directly contact protruded portions of the first conductive pattern 120 in the recess portion 125.

In addition, the second photolithography process may be performed using the alignment key 145 to further pattern the upper electrode layer 170 so that the upper electrode layer 170 overlaps the first conductive pattern 120 except for a part of the first conductive pattern 120. The MIM capacitor is formed in the recess portion 125.

A third insulating layer 180 may be formed on the second insulating layer 140 including the MIM capacitor and the alignment key 145. The third insulating layer 180 may include an oxide layer. A dual damascene process may be performed to form a second dual damascene pattern 181 throughout the second and third insulating layers 140 and 180 and the etch stop layer 130 on the memory region 101 so as to expose a part of the second conductive pattern 121.

At the same time, first dual damascene patterns 185 may be formed on the circuit region 105 throughout the third insulating layer 180 and/or the dielectric layer 160. The first dual damascene patterns 185 may expose a part of the first conductive pattern 120 which does not overlap with the upper electrode layer 170, and a part of the upper electrode layer 170.

The first wires 190 may be arranged in the first dual damascene patterns 185 so as to electrically contact the exposed portions of the first conductive pattern 120 and the upper electrode layer 170. In addition, the second wire 191 may be arranged in the second dual damascene pattern 181 so as to electrically contact the exposed part of the second conductive pattern 121.

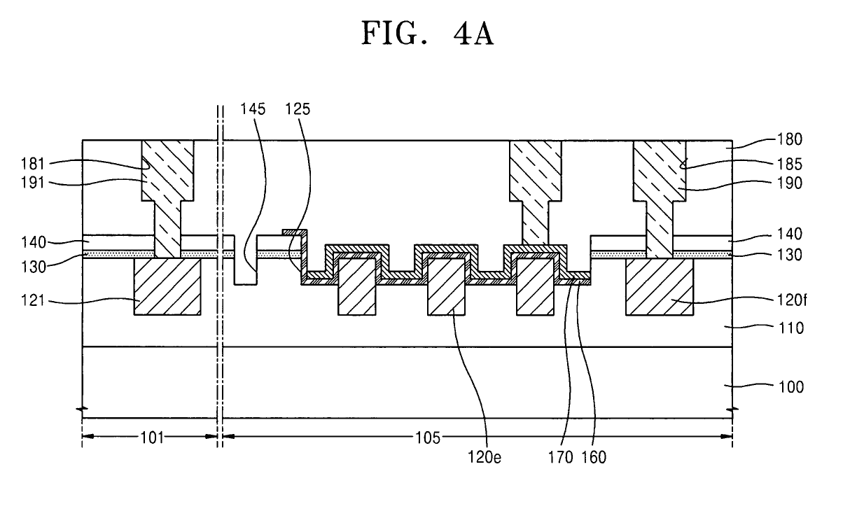

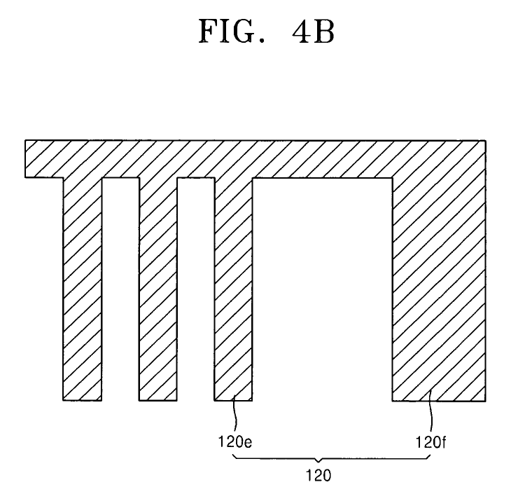

FIG. 4A is a cross-sectional view of a semiconductor device including an MIM capacitor according to another example embodiment, and FIG. 4B is a plan view of a first conductive pattern 120 shown in FIG. 4A. Referring to FIGS. 4A and 4B, the semiconductor device of the present example embodiment is the same as the semiconductor device shown in FIGS. 3A through 3C except for the structure of the first conductive pattern 120 that performs as the lower electrode of the MIM capacitor.

The first conductive pattern 120 may include a first portion 120e that is arranged in a recess portion 125 of a circuit region 105 and a second portion 120f arranged on the circuit region 105 outside of the recess portion 125. The first portion 120e may be arranged in the recess portion 125 so as to perform as the lower electrode of the MIM capacitor, and the second portion 120f performs as a contact region contacting the first wire 190 for the upper electrode of the MIM capacitor.

A dielectric layer 160 may be arranged so as to directly contact the protruded portion of the first portion 120e of the first conductive pattern 120 in the recess portion 125. An upper electrode layer 170 may be disposed on the dielectric layer 160 so as to completely overlap the first portion 120e of the first conductive pattern 120. Therefore, the MIM capacitor is arranged in the recess portion 125.

The first and second dual damascene patterns 185 and 181 may be arranged in the third insulating layer 180. The first dual damascene patterns 185 may expose a part of the upper electrode layer 170 and a part of the second part 120f of the first conductive pattern 120. First wires 190 may be arranged in the first dual damascene patterns 185 so as to electrically contact the exposed portion of the upper electrode layer 170 and the exposed portion of the second portion 120f of the first conductive pattern 120.

While the inventive concept has been particularly shown and described with reference to example embodiments thereof, it will be understood that various changes in form and details may be made therein without departing from the spirit and scope of the following claims.

1. A method of fabricating a semiconductor device including a metal-insulator-metal (MIM) capacitor, the method comprising:
forming a first insulating layer on a semiconductor substrate; forming an electrode pattern embedded in the first insulating layer on a first region of the semiconductor substrate;
forming a second insulating layer on the first insulating layer and the electrode pattern;
forming a recess portion that defines a capacitor region on the first region by etching the first and second insulating layers, wherein the electrode pattern is arranged in the recess portion and a portion of the electrode pattern protrudes from a bottom surface of the recess portion; and
forming a dielectric layer and an upper electrode layer on the bottom surface of the recess portion and the protruded portion of the electrode pattern.

2. The method of claim 1, wherein the electrode pattern includes copper (Cu).

3. The method of claim 1, wherein the forming a recess portion further comprises:
forming an alignment key to be used in forming the dielectric layer and the upper electrode layer on a remaining portion of the first region except for the recess portion, wherein the alignment key has an etching depth that is equal to a depth of the recess portion.

4. The method of claim 3, wherein the recess portion and the alignment key are formed simultaneously.

5. The method of claim 1, further comprising:
forming a third insulating layer on the second insulating layer including the recess portion, wherein the third insulating layer includes a first dual damascene pattern and a second dual damascene pattern that exposes a portion of the upper electrode layer; and
forming a first wire in the first dual damascene pattern and a second wire in the second dual damascene pattern,
wherein the second wire is electrically connected to the exposed portion of the upper electrode layer.

6. The method of claim 5, wherein the first and second wires include copper (Cu).

7. The method of claim 5, wherein the semiconductor substrate further includes a second region and the forming an electrode pattern further comprises:
forming a conductive pattern on the second region.

8. The method of claim 7, wherein the second dual damascene pattern exposes at least a portion of the upper electrode layer.

9. The method of claim 7, wherein the third insulating layer further includes a third dual damascene pattern that exposes a portion of the conductive pattern, and the exposed portion of the conductive pattern is electrically connected to a third wire arranged in the third dual damascene pattern.

10. The method of claim 7, wherein the second region includes a memory region and the first region includes a circuit region.

11. The method of claim 5, wherein prior to the forming a recess portion and the forming a dielectric layer, the method further comprising:
forming a lower electrode layer directly contacting the electrode pattern under the dielectric layer.

12. The method of claim 11, wherein a portion of the lower electrode layer corresponding to the electrode pattern is exposed by the first dual damascene pattern and directly contacts the first wire.

13. The method of claim 10, wherein the first dual damascene pattern exposes at least a portion of the lower electrode layer.

14. The method of claim 5, wherein the electrode pattern comprises:
a plurality of conductive patterns arranged in the recess portion and electrically connected to each other, and wherein
a portion of the plurality of conductive patterns are exposed by the first dual damascene pattern so as to directly contact the first wire.

15. The method of claim 5, wherein the electrode pattern comprises:
a plurality of conductive patterns arranged in the recess portion; and
a contact pattern arranged on a remaining portion of the first region except for the recess portion and electrically connected to the plurality of conductive patterns, and wherein
a portion of the contact pattern is exposed by the first dual damascene pattern to directly contact the first wire.

16. A method of fabricating a semiconductor device including a metal-insulator-metal capacitor, the method comprising:
forming a first conductive pattern structure in a first insulating layer on a semiconductor substrate such that each conductive pattern protrudes from a surface of the first insulating layer;
forming a lower electrode layer over a portion of a first insulating layer including the first conductive pattern structure; and
forming a dielectric layer and an upper electrode layer over a portion of the lower electrode layer.

17. The method of claim 16, wherein the surface of the first insulating layer in which the first conductive pattern structure is formed is a bottom surface of a recess defined by the first insulating layer.

18. The method of claim 17, further comprising:
forming a second conductive pattern structure in a non-recessed portion of the first insulating layer.
